(19) United States
(12) Patent Application Publication
(10) Pub. No.: US 2024/0096691 A1
(43) Pub. Date: Mar. 21, 2024

(54) SEMICONDUCTOR STRUCTURE AND METHOD FOR MANUFACTURING THE SAME

(71) Applicant: CHANGXIN MEMORY TECHNOLOGIES, INC., Hefei City (CN)

(72) Inventors: Mingming MA, Hefei City (CN); Zhikai WU, Hefei City (CN)

(73) Assignee: CHANGXIN MEMORY TECHNOLOGIES, INC., Hefei City (CN)

(21) Appl. No.: 18/166,492

(22) Filed: Feb. 9, 2023

(30) Foreign Application Priority Data
Sep. 16, 2022 (CN) 202211131135.2

(51) Int. Cl. H01L 21/768; H01L 21/311; H01L 23/522

(52) U.S. Cl. CPC H01L 21/76814; H01L 21/31116; H01L 23/5226; H01L 21/76843; H01L 23/53266

(57) ABSTRACT

A method for manufacturing a semiconductor structure includes: providing a substrate including a transistor structure; forming a laminated structure on the substrate, the laminated structure including a dielectric layer and an insulating layer which are sequentially stacked in a thickness direction of the substrate, and the insulating layer being arranged on a side, away from the substrate, of the dielectric layer; forming a through hole penetrating through the laminated structure in the laminated structure to expose a source/drain of the transistor structure; and etching at least part of a side wall of the through hole located in the dielectric layer to form a conductive hole in the insulating layer and the dielectric layer. An aperture size of a medial part of the conductive hole is greater than an aperture size of each of both ends of the conductive hole.

### CROSS-REFERENCE TO RELATED APPLICATION

This application claims priority to Chinese Patent Application No. 202211131135.2 filed on Sep. 16, 2022, the disclosure of which is hereby incorporated by reference in its entirety.

### BACKGROUND

A Dynamic Random Access Memory (DRAM) is a common semiconductor storage device, which includes many repeated storage units. Each storage unit usually includes a transistor and a capacitor. A gate of the transistor is connected to a Word Line (WL), a drain of the transistor is connected to a Bit Line (BL), and a source of the transistor is connected to the capacitor.

With the continuous development of a semiconductor chip, the critical size thereof is continuously reduced. When a conductive plug is manufactured in a peripheral circuit region, a mask layer is usually arranged on a laminated structure on a substrate first, the mask layer is patterned to be used as a mask, a conductive hole is formed in the laminated structure by a dry etching process, the conductive hole exposes a source or a drain of a transistor structure on the substrate, and a conductive material is deposited in the conductive hole to form the conductive plug, which is electrically connected with the source/drain of the transistor structure.

However, due to the limitation on the size and process of the transistor, the aperture size of the manufactured conductive hole is small, resulting in large resistance of the conductive plug formed in the conductive hole, thereby resulting in the technical problem of poor reliability of the electrical performance of a semiconductor structure.

### SUMMARY

The present disclosure relates to the technical field of semiconductors, in particular to a semiconductor structure and a method for manufacturing the same.

In a first aspect, the embodiments of the present disclosure provide a method for manufacturing a semiconductor structure, which includes the following operations.

A substrate including a transistor structure is provided.

A laminated structure is formed on the substrate, the laminated structure including a dielectric layer and an insulating layer which are sequentially stacked in a thickness direction of the substrate, the insulating layer being arranged on a side, away from the substrate, of the dielectric layer.

A through hole penetrating through the laminated structure is formed in the laminated structure to expose a source/drain of the transistor structure.

At least part of a side wall of the through hole located in the dielectric layer is etched to form a conductive hole in the insulating layer and the dielectric layer. Herein, an aperture size of a medial part of the conductive hole is greater than an aperture size of each of both ends of the conductive hole.

In a second aspect, the embodiments of the present disclosure also provide a semiconductor structure, which includes: a substrate, a laminated structure and a conductive hole.

The substrate y includes a transistor structure.

The laminated structure is located on the substrate. The laminated structure includes a dielectric layer and an insulating layer which are sequentially stacked in a direction perpendicular to the substrate, the insulating layer being arranged on a side, away from the substrate, of the dielectric layer.

The conductive hole penetrates through the laminated structure to expose a source/drain of the transistor structure. Herein, an aperture size of a medial part of the conductive hole is greater than an aperture size of each of both ends of the conductive hole.

### BRIEF DESCRIPTION OF THE DRAWINGS

In order to more clearly illustrate the embodiments of the present disclosure or the technical solutions in some implementations, the drawings used in the description of the embodiments or some implementations will be briefly described below. It is apparent that the drawings described below are only some embodiments of the present disclosure. Other drawings may further be obtained by those of ordinary skill in the art according to these drawings without creative efforts.

FIG. 1 is a flow diagram of a method for manufacturing a semiconductor structure according to an embodiment of the present disclosure.

FIG. 2 is a first diagrammatic cross-section of a process for manufacturing a semiconductor structure according to an embodiment of the present disclosure.

FIG. 3 is a second diagrammatic cross-section of a process for manufacturing a semiconductor structure according to an embodiment of the present disclosure.

FIG. 4 is a third diagrammatic cross-section of a process for manufacturing a semiconductor structure according to an embodiment of the present disclosure.

FIG. 5 is a fourth diagrammatic cross-section of a process for manufacturing a semiconductor structure according to an embodiment of the present disclosure.

FIG. 6 is a fifth diagrammatic cross-section of a process for manufacturing a semiconductor structure according to an embodiment of the present disclosure.

FIG. 7 is a sixth diagrammatic cross-section of a process for manufacturing a semiconductor structure according to an embodiment of the present disclosure.

Reference numerals are as follows.
100—semiconductor structure; 110—substrate; 120—laminated structure; 121—dielectric layer; 122—insulating layer;
123—through hole; 124—conductive hole; 130—conductive plug; 140—barrier layer; 150—ohmic contact layer;
200—transistor structure; 210—gate; 211—gate side wall insulating layer; 220—source/drain;
300—mask layer; 400—initial mask layer; 410—initial mask base layer;
420—initial mask pattern layer.

### DETAILED DESCRIPTION

During practical work, an inventor of the present disclosure has found that with the continuous development of a semiconductor chip, the critical size thereof is continuously reduced. When a conductive plug is manufactured in a peripheral circuit region, a mask layer is usually arranged on a laminated structure on a substrate first, the laminated structure including a dielectric layer arranged on the substrate and an insulating layer (such as a silicon nitride layer) arranged on the dielectric layer. The mask layer then is patterned, the patterned mask layer being used as a mask, and part of the laminated structure is removed by a dry etching process so as to form a through hole in the laminated structure. The through hole exposes a source or a drain of a transistor structure on the substrate. The diameter of the manufactured through hole is relatively small, generally, a pickling solution is injected into the through hole so as to take away by-products in the through hole by the pickling solution, and to enlarge the area of the through hole by the pickling solution so as to form a conductive hole. Then, a conductive material is deposited in the conductive hole to form a conductive plug, which is electrically connected with the source/drain of the transistor structure.

However, since the etching selectivity ratio of the pickling solution for the dielectric layer and a gate side wall insulating layer located at the periphery of a gate of the transistor is relatively low, the gate side wall insulating layer may be etched while etching the dielectric layer, resulting in thinning of the gate side wall insulating layer and poor isolation effect. Therefore, the pickling time should not be too long, which however may result in that the aperture size of the conductive hole will be relatively small, and therefore a subsequent deposition space of the dielectric material is insufficient, resulting in large resistance of the conductive plug formed in the conductive hole, thereby causing the technical problem of poor reliability of the electrical performance of the semiconductor structure.

In order to solve the above problems, the embodiments of the present disclosure provide a semiconductor structure and a method for manufacturing the same. Herein, through the method for manufacturing the semiconductor structure, a space size of a medial part of the formed conductive hole is greater than a space size of each of both ends of the formed conductive hole, which provides the sufficient deposition space for the subsequent dielectric material, so as to improve the deposition effect and increase the size of the conductive plug, thereby reducing the resistance of the conductive plug and improving the reliability of the electrical performance of the semiconductor structure.

In order to make the above purposes, features and advantages of the embodiments of the present disclosure clearer and understandable, the technical solutions in the embodiments of the present disclosure will be clearly and completely described below in combination with the drawings in the embodiments of the present disclosure. It is apparent that the described embodiments are only a part rather all of embodiments of the present disclosure. All other embodiments obtained by those of ordinary skill in the art based on the described embodiments of the present disclosure without creative efforts shall fall within the protection scope of the present disclosure.

The semiconductor structure provided by the embodiments of the present disclosure may be a storage device or non-storage device. The storage device may include, for example, a DRAM, a Static Random Access Memory (SRAM), a flash memory, an Electrically Erasable Programmable Read-Only Memory (EEPROM), a Phase Change Random Access Memory (PRAM), or a Magnetoresistive Random Access Memory (MRAM). The non-storage device may be a logic device (such as a microprocessor, a digital signal processor, or a microcontroller) or a device similar thereto. The embodiments of the present disclosure are illustrated with a DRAM storage device as an example.

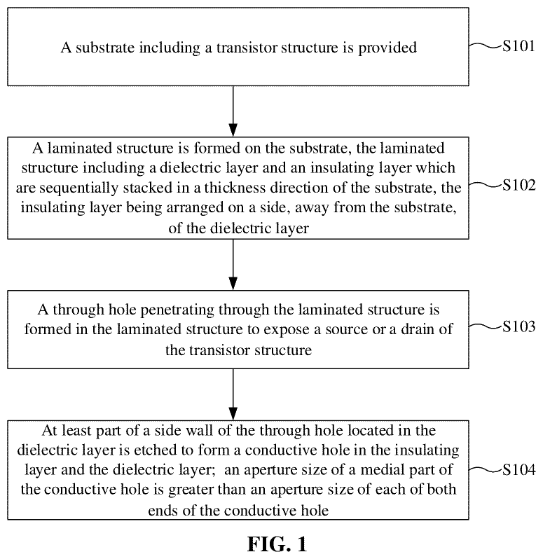

FIG. 1 is a flow diagram of a method for manufacturing a semiconductor structure according to an embodiment of the present disclosure. Referring to FIG. 1, the embodiments of the present disclosure provide a method for manufacturing a semiconductor structure, which includes the following operations.

At S101, a substrate including a transistor structure is provided.

The substrate 110 may provide a structural basis for subsequent structures and processes. The material of the substrate 110 may include any one or more of silicon, germanium, silicon germanium, silicon carbide, a silicon-on-insulator substrate, and a germanium-on-insulator substrate. In the embodiments of the present disclosure, at least part of the substrate 110 is a silicon substrate and the silicon material may be single crystal silicon. The substrate 110 may be manufactured by Chemical Vapor Deposition (CVD).

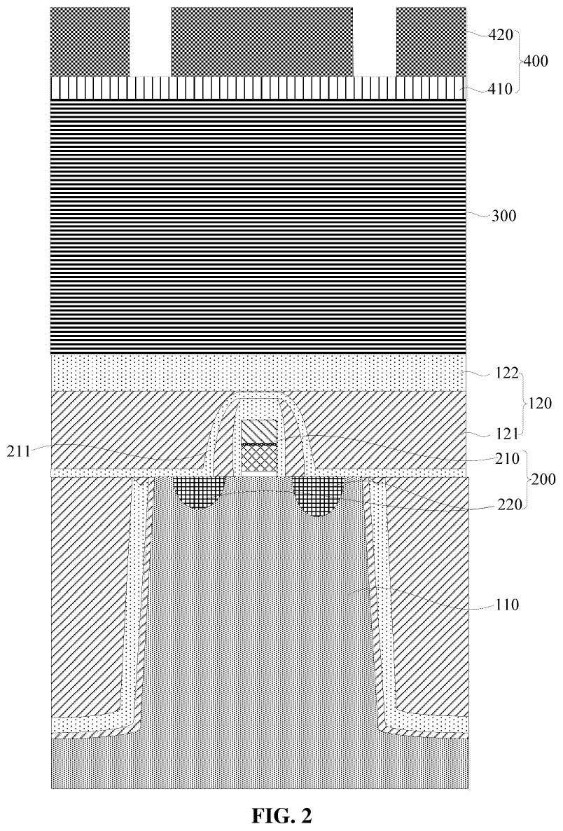

Referring to FIG. 2, the substrate 110 includes a plurality of first active regions. A plurality of transistor structures 200 are arranged in the first active regions, and the plurality of transistor structures 200 constitute a peripheral control circuit in the semiconductor structure. The peripheral control circuit is configured to realize other functions, such as logic storage, signal amplification transmission, clock regulation and control and the like in the DRAM storage device, except for signal storage. Herein, the transistor structure 200 includes a gate 210, a source, and a drain. The gate 210 of each of some transistor structures 200 may be coupled to a transistor control voltage of the peripheral control circuit in the semiconductor structure 100. The source and the drain of the transistor structure 200 are respectively coupled to a transmission voltage of the peripheral control circuit in the semiconductor structure 100. Through switching on and off a buried transistor in an array region, the peripheral control circuit realizes storage and reading of a storage unit by an external signal through the transmission voltage.

The substrate includes an array region and a peripheral region, the peripheral region being adjacent to the array region. The transistor structure 200 is located in the peripheral region. The array region includes a plurality of WLs which are arranged in parallel and spaced apart in a first direction and a plurality of BLs which are arranged in parallel and spaced apart in a second direction. Herein, the first direction and the second direction are staggered. The array region further includes a plurality of storage units, each storage unit including a buried transistor located in the array region. Herein, a gate of the buried transistor in the array region is connected to the WL, a drain of the buried transistor in the array region is connected to the BL, and a source of the buried transistor in the array region is connected to a capacitor which is subsequently manufactured. A voltage signal on the WL may control the switch-on or switch-off of the buried transistor in the array region, and then data information stored in the capacitor is read through the BL, or the data information is written into the capacitor through the BL for storage. A BL isolation structure is arranged between the adjacent BLs. Both the voltage signal of the WL and the BL transmit the data information through the peripheral control circuit.

Herein, a metal part of the gate 210 in the transistor structure 200 in the peripheral region and a metal part of the BL in the array region may be formed in the same procedure by the same material and the same process. Then, a gate side wall insulating layer 211 is formed on the metal part of the gate 210 of the transistor structure 200 in the peripheral region so as to electrically isolate the gate through the gate side wall insulating layer 211. At the same time, a BL side wall insulating layer is formed on the metal part of the BL in the array region so as to electrically isolate the BL through the BL side wall insulating layer. Herein, the gate side wall insulating layer 211 and the BL side wall insulating layer may be formed in the same procedure by the same material and the same process. Due to the technology process, the gate side wall insulating layer 211 is, for example, in a shape shown in FIG. 1. In FIG. 1, the shape of the gate side wall insulating layer 211 is of an arc-shaped structure, and the radial dimension of the gate side wall insulating layer 211 decreases from the bottom to the top.

At S102, a laminated structure is formed on the substrate, the laminated structure including a dielectric layer and an insulating layer which are sequentially stacked in a thickness direction of the substrate, the insulating layer being arranged on a side, away from the substrate, of the dielectric layer.

With continued reference to FIG. 2, the dielectric layer 121 and the insulating layer 122 which are stacked are sequentially formed on the substrate 110 by an Atomic Layer Deposition (ALD) process or a CVD process. Herein, the insulating layer 122 is arranged on a side, away from the substrate 110, of the dielectric layer 121.

Herein, the material of the dielectric layer 121 may include an oxide material. The material of the insulating layer 122 may include silicon nitride (SiN).

At S103, a through hole penetrating through the laminated structure is formed in the laminated structure to expose a source/drain of the transistor structure.

With continued reference to FIG. 2, after the laminated structure 120 is formed on the substrate 110, a mask layer 300 and an initial mask layer 400 firstly are formed on the laminated structure 120, the initial mask layer 400 being located on a side, away from the laminated structure 120, of the mask layer 300. The mask layer 300 may be a Spin On Hardmask (SOH), the material of the mask layer may be a silicon-rich compound.

The initial mask layer 400 may include an initial mask base layer 410 and an initial mask pattern layer 420. The initial mask pattern layer 420 is located on a side, away from the laminated structure 120, of the initial mask base layer 410. The initial mask base layer 410 may be formed by a deposition process such as an ALD process or a CVD process. Here, the material of the initial mask base layer 410 may be silicon oxynitride.

Then, the initial mask base layer 410 may be coated with a layer of photoresist, the material of which may be an organic compound that is sensitive to light (such as ultraviolet light), for example, poly(vinyl cinnamate). A photomask is arranged on the photoresist layer, and a mask opening is provided in the photomask. The ultraviolet light is irradiated to the surface of the photoresist through the photomask so as to cause a chemical reaction to occur in an exposed region of the photoresist, and then the photoresist in the exposed region (positive photoresist) or the photoresist in the unexposed region (negative photoresist) is dissolved and removed by a developing technique, thereby forming the initial mask pattern layer 420.

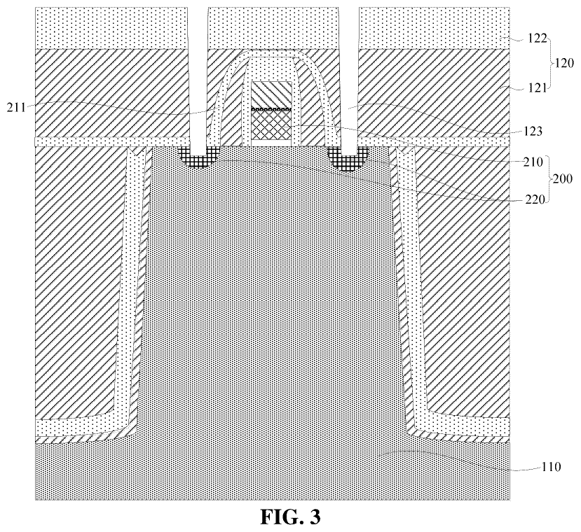

The initial mask base layer 410 and the mask layer 300 are etched using the initial mask pattern layer 420 as a mask, so as to transfer the pattern of the initial mask pattern layer 420 to the mask layer 300, thereby forming the patterned mask layer 300. Herein, the pattern on the mask layer 300 corresponds to the shape, size and position of the pattern of the through hole 123 to be manufactured in the laminated structure 120, and the laminated structure 120 is etched using the patterned mask layer 300 as a mask through the dry etching process, so as to form the through hole 123 penetrating through the laminated structure 120 in the laminated structure 120, as shown in FIG. 3. Herein, the through hole 123 penetrating through the laminated structure 120 exposes a source/drain 220 of the transistor structure 200 to facilitate the electrical connection of a conductive plug 130 subsequently formed in the through hole 123 with the source/drain 220 of the transistor.

In some embodiments, a cross section of the through hole 123 may be of any shape such as a circle, an ellipse, a square or the like. In the following embodiments, the cross-sectional of the through hole 123 which may be circular will be described as a example.

After the through hole 123 penetrating through the laminated structure 120 is formed in the laminated structure 120, the mask layer 300 on the laminated structure 120 is removed to expose the surface of the laminated structure 120.

At S104, at least part of a side wall of the through hole located in the dielectric layer is etched to form a conductive hole in the insulating layer and the dielectric layer. Herein, an aperture size of a medial part of the conductive hole is greater than an aperture size of each of both ends of the conductive hole.

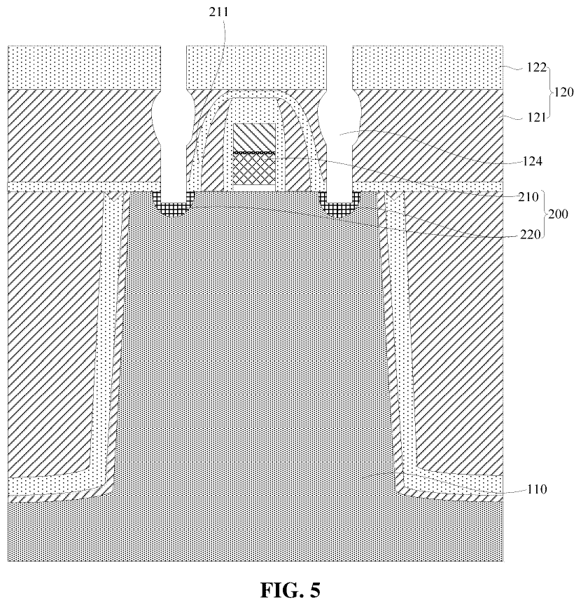

Referring to FIGS. 5 to 7, at least part of the side wall of the through hole 123 located in the dielectric layer 121 is further etched, so that the aperture size of the medial part of the conductive hole 124 is greater than the aperture size of each of both ends of the conductive hole, and a structural shape such as a “dumbbell shape” is formed to increase the surface area of the through hole 123, thereby increasing the contact area of the conductive plug 130 formed in the conductive hole 124 in the subsequent process and reducing the resistance value of the conductive plug 130.

It is to be noted that the operation that the conductive hole 124 is formed in the insulating layer 122 and the dielectric layer 121 means that, the structure of the through hole 123, obtained after at least part of the side wall of the through hole 123 located in the dielectric layer 121 is further etched, is formed as the conductive hole 124. Herein, the material of the insulating layer may include silicon nitride and the like.

In the above solution, at least part of the side wall of the through hole 123 located in the dielectric layer 121 is further etched, so that the aperture size of the medial part of the formed conductive hole 124 is greater than the aperture size of each of both ends of the formed conductive hole, that is, the surface area of the conductive hole 124 is increased. In this way, the contact area of the conductive plug 130 formed in the conductive hole 124 in the subsequent process may be increased, so that the resistance of the conductive plug 130 may be reduced and the electrical performance of the semiconductor structure 100 may be improved.

The specific steps of etching at least part of the side wall of the through hole 123 located in the dielectric layer 121 to form the conductive hole 124 in the insulating layer 122 and the dielectric layer 121, the aperture size of the medial part of the conductive hole 124 being greater than the aperture size of each of both ends of the conductive hole will be described in detail below in combination with the drawings.

In the embodiments of the present disclosure, after the through hole 123 is formed in the laminated structure 120 by the dry etching process, when the through hole 123 is formed by etching the laminated structure 120 by the dry etching gas, elements such as fluorine (F) and carbon (C) in the dry etching gas react with the silicon material in the laminated structure 120 to form by-products such as a high molecular polymer, and the by products such as the high molecular polymer have a strong viscosity and adhere to the hole wall of the through hole 123 to form an adhesion layer. Therefore, in the embodiments of the present disclosure, after the through hole 123 is formed in the laminated structure 120, oxygen (02) may be introduced into the through hole 123 first, so that the adhesion layer reacts with the oxygen to form by-products that do not readily adhere to the hole wall.

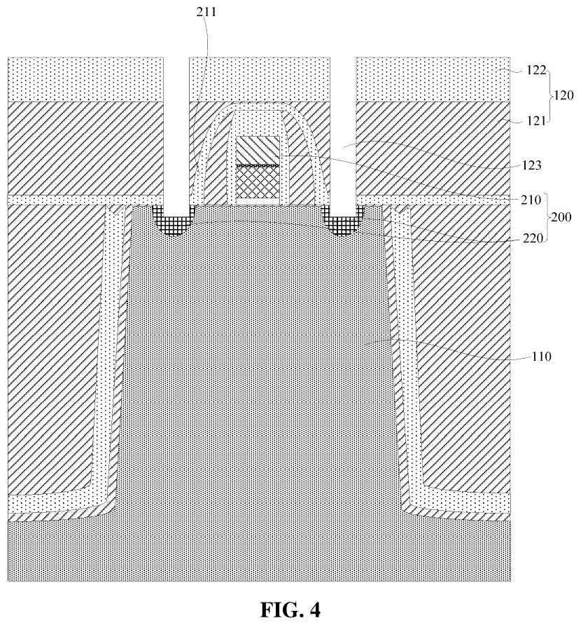

Referring to FIG. 4, after the oxygen is introduced into the through hole 123, the by-products obtained after the oxygen reacts with the adhesion layer and the rest of the adhesion layer may be removed by a pickling solution. Exemplarily, the pickling solution may be a mixture solution of hydrogen oxide and hydrofluoric acid. Herein, an etching selectivity ratio of the adhesion layer and the by-products to the gate side wall insulating layer 211 may be 3-5:1 or higher, and the pickling time is controlled so that the gate side wall insulating layer 211 is substantially not etched when the by-products obtained after the oxygen reacts with the adhesion layer and the rest of the adhesion layer are removed by the pickling solution, thereby avoiding increasing the electric leakage phenomenon of the gate 210.

In addition, the by-products obtained after the oxygen reacts with the adhesion layer and the rest of the adhesion layer are removed by the pickling solution, so that the aperture size of the through hole 123 may be further increased to provide a space for the subsequent deposition of the dielectric material, thereby increasing the contact area of the conductive plug 130 subsequently formed in the through hole 123, reducing the resistance value of the conductive plug 130 and improving the reliability of the electrical performance of the semiconductor structure.

Then, referring to FIG. 5, in some embodiments, at least part of the side wall of the through hole 123 located in dielectric layer 121 may be continued to be etched by the dry etching gas. Herein, a gas flow of the dry etching gas at the medial part of the through hole 123 is greater than a gas flow of the dry etching gas at each of both ends of the through hole 123.

It is understandable that the gas flow of the dry etching gas at the medial part of the through hole 123 is greater than the gas flow of the dry etching gas at each of both ends of the through hole 123 to increase the etched amount of the medial part of the through hole 123, so that the etching rate of the medial part of the through hole 123 is greater than the etching rates of both ends of the through hole, thereby enabling the aperture size of the medial part of the formed conductive hole 124 to be greater than the aperture size of each of both ends of the formed conductive hole. Different kinetic energy may be given to the dry etching gas by gas temperature control, so that the dry etching gas moves downward to different locations of the through hole 123 to stay for reaction.

Herein, the medial part of the through hole 123 may be located at ½-⅓ of a height of the conductive hole 124 from top to bottom.

In some embodiments, the dry etching gas includes a main etching gas, ammonia gas and an inert gas. The main etching gas may be fluorine (F)-containing gas, for example, the main etching gas may be mixed gas of hydrogen fluoride (HF) and hydrogen nitride (NH₃), and the inert gas may be argon. It is understandable that the inert gas may provide a certain ion bombardment to adjust the etching rate according to specific requirements.

In some embodiments, an inlet flow ratio among the main etching gas, the ammonia gas and the inert gas may be 4:4:1 to 2:2:1. For example, the inlet flow ratio among the main etching gas, the ammonia gas and the inert gas is 4:4:1; or, the inlet flow ratio among the main etching gas, the ammonia gas and the inert gas is 3:3:1; or, the inlet flow ratio among the main etching gas, the ammonia gas and the inert gas is 2:2:1, and the specific ratio thereof may be adaptively designed according to practical requirements, which is not specifically limited here.

An introduction time of the dry etching gas is 20-30 s, which may ensure the area of the middle of the conductive hole 124, and avoid further etching the dielectric layer 121 due to too long introduction time, causing the conductive hole 124 to be skewed, which is not conducive to subsequent deposition.

In some embodiments, when the side wall of the through hole 123 is etched by the dry etching gas, the etching selectivity ratio of the dielectric layer 121 to the insulating layer 122 is greater than 10:1, for example, the etching selectivity ratio is 15:1, 20:1, 50:1, 100:1, etc. In this way, the size of the through hole 123 in the insulating layer 122 may be substantially unchanged by selecting the dry etching gas with a higher etching selectivity ratio and by controlling the etching time of the side wall of the conductive hole 124. The hole wall of the through hole 123 in the dielectric layer 121 is further etched by the dry etching gas, so that the size of the through hole 123 in the dielectric layer 121 increases. In addition, by controlling the flow rate of the dry etching gas entering the through hole 123 in the dielectric layer 121, the through hole 123 in the dielectric layer 121 may be etched in different etch amounts at different locations, for example, the flow rate of the dry etching gas on the side, close to the insulating layer 122, in the through hole 123 in the dielectric layer 121 is greater than the flow rate of the dry etching gas on the side, close to the substrate 110, in the through hole 123 in the dielectric layer 121, so that the aperture size of the medial part of the formed conductive hole 124 is greater than the aperture size of each of both ends of the formed conductive hole, so as to avoid damage to the gate side wall insulating layer 211. At the same time, the surface area of the conductive hole 124 may be increased, so that the contact area of the conductive plug 130 formed in the subsequent process may be increased, so as to reduce the resistance value of the conductive plug 130, thereby improving the reliability of the electrical performance of the semiconductor structure 100.

In addition, when the dielectric layer 121 is etched using the dry etching gas, the insulating layer 122 is substantially not etched. In this way, when the dry etching gas enters the through hole 123, the dry etching gas is buffered or changes the movement direction and gathers below the insulating layer 122 due to the blocking of the insulating layer 122 at the top of the dielectric layer 121, so that the flow rate of the dry etching gas at the medial part of the through hole 123 in the dielectric layer 121 (namely, the end, close to the insulating layer 122, of the dielectric layer 121) is further increased, and thus the etched amount of the medial part of the through hole 123 can be increased, while the end, close to the substrate 110, of the through hole 123 is substantially not etched. Therefore, the aperture size of the medial part of the finally obtained conductive hole 124 is greater than the aperture size of each of both ends thereof.

In some embodiments, the duration of etching at least part of the side wall of the through hole 123 located in the dielectric layer 121 by the dry etching gas in the through hole 123 may be 20 s to 30s. By controlling the duration of etching at least part of the side wall of the through hole 123 located in the dielectric layer 121 by the dry etching gas, the accuracy of the etched part of the through hole 123 may be further precisely controlled to ensure that the insulating layer 122 and the bottom of the through hole 123 are not substantially etched, thereby improving the dimensional accuracy of the formed conductive hole 124.

Exemplarily, the duration of etching at least part of the side wall of the through hole 123 located in the dielectric layer 121 by the dry etching gas may be controlled to 20s, 25s, 28s, 30s, etc. which may be specifically and adaptively designed according to practical situations, and is not specifically limited here.

In some embodiments, the dry etching gas may be mixed gas of HF and NH₃, the etching selectivity ratio is, for example, 20:1, the etching duration is 26 s, and when the side wall of the conductive hole 124 is etched by the dry etching gas, specific reaction mechanisms are as follows.

SiO₂+4HF+4NH₃→SiF₄+2H₂O+4NH₃ (1)

SiF₄+2HF+2NH₃→(NH₄)₂SiF₆ (2)

(NH₄)₂SiF₆→SiF₄+2NH₃+2HF

As can be seen from the above solution, the fluorine-containing dry etching gas is introduced into the through hole 123 for 20 s-30 s, for example, 26 s. In this way, by controlling the etching time and the etching selectivity ratio, it is ensured that the insulating layer 122 on the dielectric layer 121 and the gate side wall insulating layer 211 are hardly etched during the etching process so as to obtain the relatively ideal size of the conductive hole 124 without affecting other properties of the semiconductor structure 100. In addition, due to the blocking of the insulating layer 122 at the top of the dielectric layer 121 during etching, the dry etching gas is buffered or changes the movement direction and gathers below the insulating layer 122, so that the flow rate of the dry etching gas of the medial part of the through hole 123 (namely, the end, close to the insulating layer 122, of the dielectric layer 121) is increased. Therefore, the etched amount of the medial part of the through hole 123 may be increased, so that the aperture size of the medial part of the finally obtained conductive hole 124 is greater than the aperture size of each of both ends thereof, for example, the size difference between the widest aperture size of the medial part of the conductive hole 124 and the aperture size of each of both ends of the conductive hole 124 is in a range of about 6 nm to 7 nm.

Since at least part of the side wall in the dielectric layer 121 is etched by adopting the dry etching gas, the dry etching gas may also react with the silicon material in the dielectric layer 121 to form some by-products. Therefore, after the conductive hole 124 is formed in the dielectric layer 121 and the insulating layer 122, the oxygen may be continued to be introduced into the conductive hole 124, so that the oxygen reacts with the by-products to form by-products that do not readily adhere to, and then a pickling solution is introduced into the conductive hole 124 so as to remove the by-products on the bottom wall and the side wall of the conductive hole 124 through the pickling solution. At the same time, by introducing the pickling solution for a short time, smoothness of the side wall of the conductive hole 124 may also be ensured, thereby increasing the surface area of the conductive hole 124.

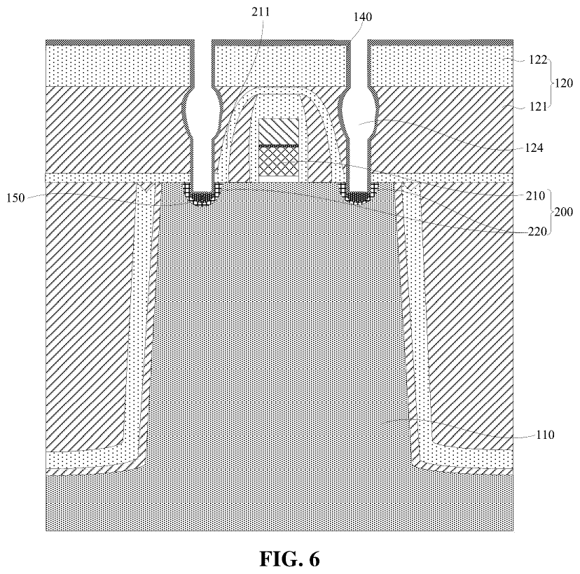

In some embodiments, after the by-products formed on the hole surface of the conductive hole 124 (that is. the bottom wall and the side wall of the conductive hole 124) are removed by the pickling solution, a metal layer may be formed on the hole surface of the conductive hole 124 and then a heat treatment may be performed on the conductive hole 124 to form an ohmic contact layer 150 on the hole surface of the conductive hole 124, as shown in FIG. 6. Herein, the material of the ohmic contact layer 150 may be metal silicide.

It is understandable that the ohmic contact layer 150 is formed on the hole surface of the conductive hole 124, so that the contact resistance of the conductive plug 130 formed in the conductive hole 124 in the subsequent process and the source/drain 220 may be reduced.

With continued reference to FIG. 6, after the ohmic contact layer 150 is formed on the hole surface of the conductive hole 124, a barrier layer 140 is formed on the ohmic contact layer 150.

Here, the barrier layer 140 may be formed on the ohmic contact layer 150 by an ALD process or a CVD process, and the material of the barrier layer 140 may be titanium nitride (TiN).

It is understandable that the barrier layer 140 is formed in the conductive hole 124, so as to avoid ion diffusion between the conductive plug 130 formed in the conductive hole 124 in the subsequent process and the dielectric layer 121.

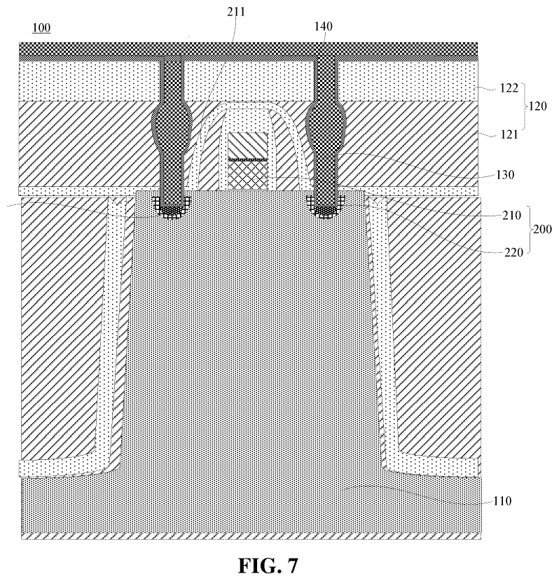

After the barrier layer 140 is formed in the conductive hole 124, the method includes that: a conductive metal material is deposited in the conductive hole 124 to form a conductive plug 130, as shown in FIG. 7, to realize the electrical conduction of the source/drain 220 and a capacitor, a BL or other structure through the conductive plug 130.

Herein, the material of the conductive plug 130 may be a conductive material such as tungsten (W).

In addition, when the conductive metal material is deposited in the conductive hole, a conductive metal material is also deposited in the same process in the array region, for example, between adjacent two BLs. After the conductive metal material is deposited between the adjacent BLs, the conductive metal material is patterned to form a capacitor pad, so that a capacitor manufactured later may be electrically connected with the buried transistor in the array region, and the capacitor pad through the capacitor plug.

With continued reference to FIGS. 6 and 7, the embodiments of the present disclosure further provide a semiconductor structure 100, which includes: a substrate 110, a laminated structure 120 and a conductive hole 124. Herein, the substrate 110 may be a single layer structure or a multi-layer composite structure. The substrate 110 includes a transistor structure 200, the transistor including a gate 210, a source and a drain.

The laminated structure 120 is located on the substrate 110, and the laminated structure 120 includes a dielectric layer 121 and an insulating layer 122 which are sequentially stacked in a direction perpendicular to the substrate 110, the insulating layer 122 being arranged on a side, away from the substrate 110, of the dielectric layer 121.

A conductive hole 124 penetrates through the laminated structure 120 to expose the source/drain 220 of the transistor structure 200. Herein, an aperture size of a medial part of the conductive hole 124 is greater than an aperture size of each of both ends of the conductive hole.

In the above solution, the aperture size of the medial part of the conductive hole 124 is greater than the aperture size of each of both ends of the conductive hole, so that the surface area of the conductive hole 124 may be increased to provide sufficient space for subsequent deposition of the dielectric material, thereby increasing the contact area of the conductive plug 130 formed in the conductive hole 124, reducing the resistance of the conductive plug 130 and improving the reliability of the electrical performance of the semiconductor structure 100.

Herein, a cross section of the conductive hole 124 may be of any shape such as a circle, an ellipse, a square or the like. In the embodiments of the present disclosure, the cross section of the conductive hole 124 which is of a circle shape will be described as an example.

In some embodiments, a size difference between the aperture size at the widest location of the medial part of the conductive hole 124 and the aperture size of each of both ends of the conductive hole 124 is, for example, 6 nm to 7 nm. For example, the size difference between the aperture size at the widest location of the medial part of the conductive hole 124 and the aperture size of each of both ends of the conductive hole 124 is, for example, 6 nm, 6.2 nm, 6.5 nm, 6.8 nm, 7 nm or the like.

In some embodiments, in a direction from the insulating layer 122 to the substrate 110 (that is, from top to bottom in FIG. 6), the medial part of the conductive hole 124 is located at ½-⅓ of the height of the conductive hole 124, that is, a distance between the widest location of the medial part of the conductive hole 124 and the bottom surface of the insulating layer 122 is ½-⅓ of the height of the conductive hole 124. For example, the distance between the widest location of the medial part of the conductive hole 124 and the bottom surface of the insulating layer 122 is ½ or ⅓ of the height of the conductive hole 124, so that the aperture size of the medial part of the conductive hole 124 is greater than the size of each of both ends of the conductive hole, so as to increase the surface area of the conductive hole 124, thereby increasing the contact area of the conductive plug 130 formed in the conductive hole 124, reducing the resistance of the conductive plug 130 and improving the reliability of the electrical performance of the semiconductor structure 100.

In some embodiments, the conductive plug 130 is arranged in the conductive hole 124, and the material of the conductive plug 130 may include a conductive material such as tungsten metal, so that the conductive plug 130 is electrically connected to the source/drain 220 of the transistor structure 200 exposed in the conductive hole 124.

Specifically, the conductive hole 124 exposes the source/drain 220 of the transistor structure 200 in the substrate 110, and after the conductive plug 130 is formed in the conductive hole 124, the conductive plug 130 is electrically connected to the source/drain 220, so that the source/drain 220 of the transistor structure 200 may be electrically connected to the capacitor or the BL through the conductive plug 130.

In some embodiments, with continued reference to FIG. 6, the barrier layer 140 is further arranged between conductive plug 130 and the hole surface of conductive hole 124. Herein, the barrier layer 140 may be a titanium nitride (TiN) layer to avoid ion diffusion between the conductive plug 130 and the dielectric layer 121 by the barrier layer 140.

In order to reduce the contact resistance of the conductive plug 130 and the source/drain 220, in the embodiments of the present disclosure, the ohmic contact layer 150 is further arranged between the barrier layer 140 and the hole surface of the conductive hole 124. Herein, the material of the ohmic contact layer 150 may be metal silicide to reduce the contact resistance of the conductive plug 130 through the ohmic contact layer 150.

According to the semiconductor structure and the method for manufacturing the same provided by the embodiments of the present disclosure, the method for manufacturing the semiconductor structure provided by the embodiment of the present disclosure includes that: a substrate including a transistor structure is provided; a laminated structure is formed on the substrate, the laminated structure including a dielectric layer and an insulating layer which are sequentially stacked in a thickness direction of the substrate, and the insulating layer being arranged on a side, away from the substrate, of the dielectric layer; a through hole penetrating through the laminated structure is formed in the laminated structure to expose a source/drain of the transistor structure; and at least part of a side wall of the through hole located in the dielectric layer is etched to form a conductive hole in the insulating layer and the dielectric layer. Herein, an aperture size of a medial part of the conductive hole is greater than an aperture size of each of both ends of the conductive hole. In the above solution, the aperture size of the medial part of the conductive hole formed in the insulating layer and the dielectric layer is greater than the aperture size of each of both ends thereof by etching at least part of the side wall of the through hole located in the dielectric layer, so that the size of the conductive plug formed in the conductive hole may be increased, thereby reducing the resistance of the conductive plug and improving the reliability of the electrical performance of the semiconductor structure.

The various embodiments or implementation modes in the present specification are described in a progressive manner, and each embodiment focuses on differences from other embodiments, and the same similar parts between the various embodiments can be referred to each other.

In the description of the present specification, descriptions of the reference terms “one implementation mode”, “some implementation mode”, “a schematic implementation mode”, “an example”, “a specific example”, “some examples”, or the like mean that specific features, structures, materials, or characteristics described in combination with the implementation mode or the example are included in at least one implementation mode or example of the present disclosure. In this specification, schematic expressions of the above terms do not necessarily refer to the same implementation mode or example. Furthermore, the specific features, structures, materials, or characteristics described may be combined in any suitable manner in any one or more implementation modes or examples.

Finally, it is to be noted that the above embodiments are only intended to illustrate the technical solutions of the present disclosure, but not intended to limit the present disclosure. Although the present disclosure is described in detail with reference to the foregoing embodiments, it should be understood by those of ordinary skill in the art that: they may still make modifications to the technical solutions described in the foregoing embodiments or equivalent replacements to part or all of the technical features. These modifications or replacements do not make the essence of the corresponding technical solutions departing from the scope of the technical solutions of the embodiments of the present disclosure.

What is claimed is:

1. A method for manufacturing a semiconductor structure, comprising:
providing a substrate comprising a transistor structure;
forming a laminated structure on the substrate, the laminated structure comprising a dielectric layer and an insulating layer which are sequentially stacked in a thickness direction of the substrate, the insulating layer being arranged on a side, away from the substrate, of the dielectric layer;
forming a through hole penetrating through the laminated structure in the laminated structure to expose a source/drain of the transistor structure; and
etching at least part of a side wall of the through hole located in the dielectric layer to form a conductive hole in the insulating layer and the dielectric layer; wherein an aperture size of a medial part of the conductive hole is greater than an aperture size of each of both ends of the conductive hole.

2. The method for manufacturing the semiconductor structure of claim 1, wherein etching at least part of the side wall of the through hole located in the dielectric layer to form the conductive hole in the insulating layer and the dielectric layer comprises:
etching at least part of the side wall of the through hole located in the dielectric layer by a dry etching gas, wherein a gas flow of the dry etching gas at the medial part of the through hole is greater than a gas flow of the dry etching gas at each of both ends of the through hole.

3. The method for manufacturing the semiconductor structure of claim 2, wherein the dry etching gas comprises: a main etching gas, ammonia gas and an inert gas, an inlet flow ratio among the main etching gas, the ammonia gas and the inert gas being 4:4:1 to 2:2:1; and
the main etching gas is a fluorine-containing gas.

4. The method for manufacturing the semiconductor structure of claim 3, wherein an etching selectivity ratio of the dielectric layer to the insulating layer is greater than 10:1 when the side wall of the through hole is etched by the dry etching gas.

5. The method for manufacturing the semiconductor structure of claim 4, wherein the duration of etching at least part of the side wall of the through hole located in the dielectric layer by the dry etching gas is 20 s to 30 s.

6. The method for manufacturing the semiconductor structure of claim 2, before etching at least part of the side wall of the through hole located in the dielectric layer by the dry etching gas, further comprising:
introducing oxygen into the through hole to remove an adhesion layer formed on the side wall of the through hole; and
removing by-products obtained after the oxygen reacts with the adhesion layer and the rest of the adhesion layer by a pickling solution.

7. The method for manufacturing the semiconductor structure of claim 1, after etching at least part of the side wall of the through hole located in the dielectric layer to form the conductive hole in the insulating layer and the dielectric layer, further comprising:
forming a conductive plug in the conductive hole.

8. The method for manufacturing the semiconductor structure of claim 7, before forming the conductive plug in the conductive hole, further comprising:
forming a barrier layer on a hole surface of the conductive hole.

9. The method for manufacturing the semiconductor structure of claim 8, wherein forming the barrier layer on the hole surface of the conductive hole comprises:
forming a metal layer on the hole surface of the conductive hole and performing a heat treatment on the conductive hole to form an ohmic contact layer on the hole surface of the conductive hole; and
forming the barrier layer on the ohmic contact layer.

10. A semiconductor structure, comprising:
a substrate comprising a transistor structure;
a laminated structure located on the substrate, the laminated structure comprising a dielectric layer and an insulating layer which are sequentially stacked in a direction perpendicular to the substrate, the insulating layer being arranged on a side, away from the substrate, of the dielectric layer; and
a conductive hole penetrating through the laminated structure to expose a source/drain of the transistor structure, wherein an aperture size of a medial part of the conductive hole is greater than an aperture size of each of both ends of the conductive hole.

11. The semiconductor structure of claim 10, wherein a size difference between the aperture size of the medial part of the conductive hole and the aperture size of each of both ends of the conductive hole is in a range of 6 nm to 7 nm.

12. The semiconductor structure of claim 10, wherein the medial part of the conductive hole is close to a bottom surface of the insulating layer, and a distance between a widest location of the medial part of the conductive hole and the bottom surface of the insulating layer is ½ to ⅓ of a height of the conductive hole.

13. The semiconductor structure of claim 10, wherein a conductive plug is arranged in the conductive hole, and the conductive plug is connected to the source/drain of the transistor structure.

14. The semiconductor structure of claim 13, wherein a barrier layer is further arranged between the conductive plug and a hole surface of the conductive hole.

15. The semiconductor structure of claim 14, wherein an ohmic contact layer is further arranged between the barrier layer and the hole surface of the conductive hole.

16. The semiconductor structure of claim 15, wherein the barrier layer is a titanium nitride layer.

17. The semiconductor structure of claim 15, wherein the ohmic contact layer is a metal silicide layer.
